(19) United States
(12) Patent Application Publication
(10) Pub. No.: US 2022/0246715 A1
(43) Pub. Date: Aug. 4, 2022

(54) CAPACITOR UNIT AND MANUFACTURING PROCESS THEREOF

(71) Applicant: Powerchip Semiconductor Manufacturing Corporation, Hsinchu City (TW)

(72) Inventors: KUO-YU YEH, Miaoli County (TW); WEI-YU LIN, Hsinchu City (TW)

(21) Appl. No.: 17/390,987

(22) Filed: Aug. 1, 2021

(30) Foreign Application Priority Data
Feb. 1, 2021 (TW) 110103641

(51) Int. Cl. H01L 49/02; H01G 13/00; H01G 4/30

(52) U.S. Cl. CPC H01L 28/60; H01G 4/30; H01G 13/00

(57) ABSTRACT

A capacitor unit and a manufacturing process thereof are provided. The manufacturing process includes: providing a carrier; forming a metallic layer on the carrier, defining a plurality of metallic blocks in the metallic layer, and forming a middle stacking structure on each of the metallic blocks, wherein the middle stacking structure includes a first capacitance conductive layer, a second capacitance conductive layer, and a capacitance insulation layer located between the first and second capacitance conductive layers, wherein the first capacitance conductive layer is electrically connected to the corresponding one of the metallic blocks; and removing the carrier to expose the metallic blocks so as to form a plurality of independent capacitor units, so as to fabricate double sided capacitor units with high capacitance.

### CROSS-REFERENCE TO RELATED APPLICATIONS

This application claims the priority of Republic of China Patent Application No. 110103641 filed on Feb. 1, 2021, in the State Intellectual Property Office of the R.O.C., the disclosure of which is incorporated herein by reference.

### BACKGROUND OF THE INVENTION

### Field of the Invention

The present invention relates to semiconductor technologies, and more particularly, to a capacitor integrated structure, a capacitor unit and a manufacturing process thereof.

### Descriptions of the Related Art

Current complete capacitor manufacturing process, such as for MLCC (multi-layer ceramic chip) capacitors, includes powder milling, foil casting, printing, stacking, laminating, cutting, BBO (binder burn out), sintering, dipping, curing, electroplating, testing, and taping, etc. This process is quite mature, though complicated, giving the capacitors in sufficient supply and stable production for long time. Recently with technological innovations such as Internet, 5G communications, artificial intelligence, electric cars and so on, and with functional improvements of various electronic products, there are more and more demands in types and numbers of components being adopted. Active components are required with increased quantities and higher precision, thus greatly raising the number of passive components that are to be used with the active components, especially MLCC capacitors. This thereby results in short supply of the passive components, while manufacturers thereof have not yet found a solution to massive production to meet the market demands for passive components. Moreover, another issue is about fitting all required components in a limited space in order to have a high density layout of components, which must be achieved by using compact components with reduced area and/or volume. This is however quite challenging to conventional capacitor manufacturing technique in terms of size reduction or product precision improvement.

In view of this, compared to conventional MLCC production, the present invention uses different material, structure and manufacturing process so as to provide another option of capacitor for the market. The present invention also makes it easier to achieve area reduction of capacitors and thus improves product precision. The present invention further avoids a high temperature calcination procedure of the conventional MLCC manufacturing process, thereby in favor of energy saving, carbon reduction and cost decrease.

### SUMMARY OF THE INVENTION

In view of the above drawbacks in the prior art, a primary object of the present invention is to provide a capacitor unit and a manufacturing process thereof, thereby making double sided capacitor units with high capacitance.

In order to achieve the above objectives and other related objectives, an embodiment of the present application provides a manufacturing process of a capacitor unit, including: providing a carrier; forming a metallic layer on the carrier, defining a plurality of metallic blocks of the metallic layer, and forming a middle stacking structure on each of the metallic blocks, wherein the middle stacking structure includes a first capacitance conductive layer, a second capacitance conductive layer, and a capacitance insulation layer located between the first capacitance conductive layer and the second capacitance conductive layer, wherein the first capacitance conductive layer is electrically connected to the corresponding one of the metallic blocks; and removing the carrier to expose the metallic blocks so as to form a plurality of independent capacitor units; wherein each of the metallic blocks is used as a bottom electrode of each of the capacitor units, and the second capacitance conductive layer of the middle stacking structure is used as a top electrode of each of the capacitor units, so as to fabricate double sided capacitor units with high capacitance.

Preferably, in the manufacturing process of capacitor unit said above, wherein the carrier is a glass carrier.

Preferably, in the manufacturing process of capacitor unit said above, wherein further including: forming a release layer on the carrier, and forming the metallic layer on the release layer.

Preferably, in the manufacturing process of capacitor unit said above, wherein the step of forming a middle stacking structure on each of the metallic blocks further includes: forming the first capacitance conductive layer on each of the metallic blocks; forming the capacitance insulation layer on the first capacitance conductive layer; and forming the second capacitance conductive layer on the capacitance insulation layer.

Preferably, in the manufacturing process of capacitor unit said above, wherein the step of forming a middle stacking structure on each of the metallic blocks further includes: forming an insulating material layer on each of the metallic blocks; forming a plurality of trenches in the insulating material layer to expose each of the metallic blocks to define a raised sub-structure on each of the metallic blocks; forming the first capacitance conductive layer having a substantially uniform thickness along a surface of the raised sub-structure and an exposed surface of each of the metallic blocks; forming the capacitance insulation layer having a substantially uniform thickness along a surface of the first capacitance conductive layer; and forming the second capacitance conductive layer on the capacitance insulation layer, wherein the second capacitance conductive layer has a lower surface extended along a surface of the capacitance insulation layer.

Preferably, in the manufacturing process of capacitor unit said above, wherein the horizontal cross section of each of the trenches can be polygonal, round or rectangular.

Preferably, in the manufacturing process of capacitor unit said above, wherein the vertical cross section of each of the trenches can be triangular, rectangular or trapezoid.

Preferably, in the manufacturing process of capacitor unit said above, wherein the raised sub-structure has a height of 5 to 150 micrometers.

Preferably, in the manufacturing process of capacitor unit said above, wherein further including: the use of the photolithography, laser or dry etching processing used in the formation of the raised sub-structure.

Preferably, in the manufacturing process of capacitor unit said above, wherein the first capacitance conductive layer and the second capacitance conductive layer are formed by sputtering or electroplating.

Preferably, in the manufacturing process of capacitor unit said above, wherein the first capacitance conductive layer includes at least one metallic sub-layer.

Another embodiment of the present application provides a capacitor unit including: a bottom electrode; a raised sub-structure provided on the bottom electrode and having a plurality of trenches exposing the bottom electrode; a first capacitance conductive layer formed on a surface of the raised sub-structure and a surface of the bottom electrode, the first capacitance conductive layer having a substantially uniform thickness; a capacitance insulation layer formed on a surface of the first capacitance conductive layer and having a substantially uniform thickness; and a top electrode covering a surface of the capacitance insulation layer, wherein a side of the top electrode abutting the capacitance insulation layer is extended along the surface of the capacitance insulation layer.

Preferably, in the capacitor unit said above, wherein the first capacitance conductive layer has at least one metallic sub-layer.

Preferably, in the capacitor unit said above, wherein the horizontal cross section of each of the trenches can be polygonal, round or rectangular.

Preferably, in the capacitor unit said above, wherein the vertical cross section of each of the trenches can be triangular, rectangular or trapezoid.

Another embodiment of the present application provides a manufacturing process of a capacitor unit, including: providing a carrier; forming a metallic layer on the carrier, and defining a plurality of metallic blocks of the metallic layer; forming a middle stacking structure on each of the metallic blocks, wherein the middle stacking structure includes a second capacitance conductive layer, and a capacitance insulation layer located between each of the metallic blocks and the second capacitance conductive layer; and removing the carrier to expose the metallic blocks so as to form a plurality of independent capacitor units; wherein each of the metallic blocks is used as a bottom electrode of each of the capacitor units, and the second capacitance conductive layer of the middle stacking structure is used as a top electrode of each of the capacitor units, so as to fabricate double sided capacitor units with high capacitance.

In summary, the present invention is to provide a capacitor unit and a manufacturing process thereof, for producing a high capacitance double-sided capacitor unit. Compared to the conventional capacitor manufacturing process, the present invention simplifies capacitor production to reduce manufacture costs, and has a raised sub-structure formed in the capacitor unit to increase an extension length of various capacitance conductive layers in the capacitor unit and thereby improve capacitance of the double-sided capacitor unit.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1 to 19 are schematic diagrams showing steps of a manufacturing process of a capacitor unit according to the present invention.

FIGS. 20 to 26 are schematic diagrams of a capacitor unit according to different embodiments of the present invention.

### DETAILED DESCRIPTION OF THE PREFERRED EMBODIMENT

Embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like components.

In view of various issues existing in the prior art, the present invention provides a capacitor unit and a manufacturing process thereof.

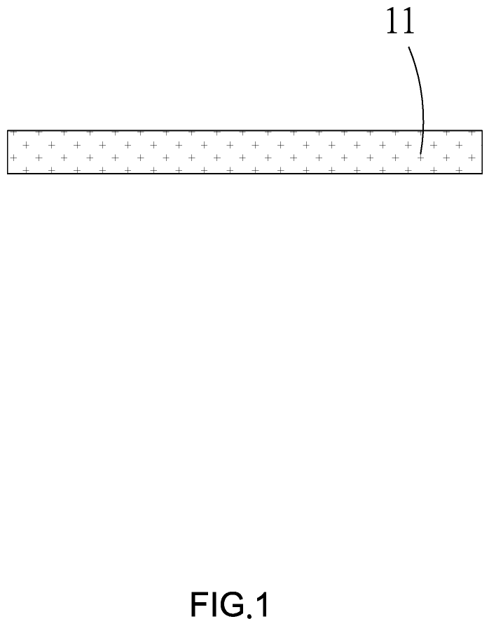

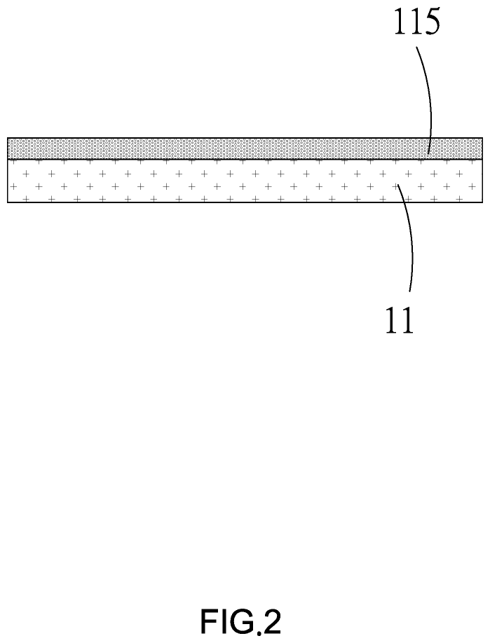

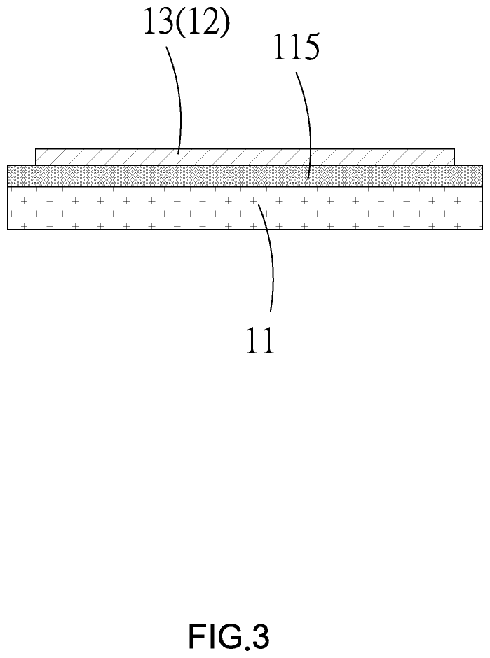

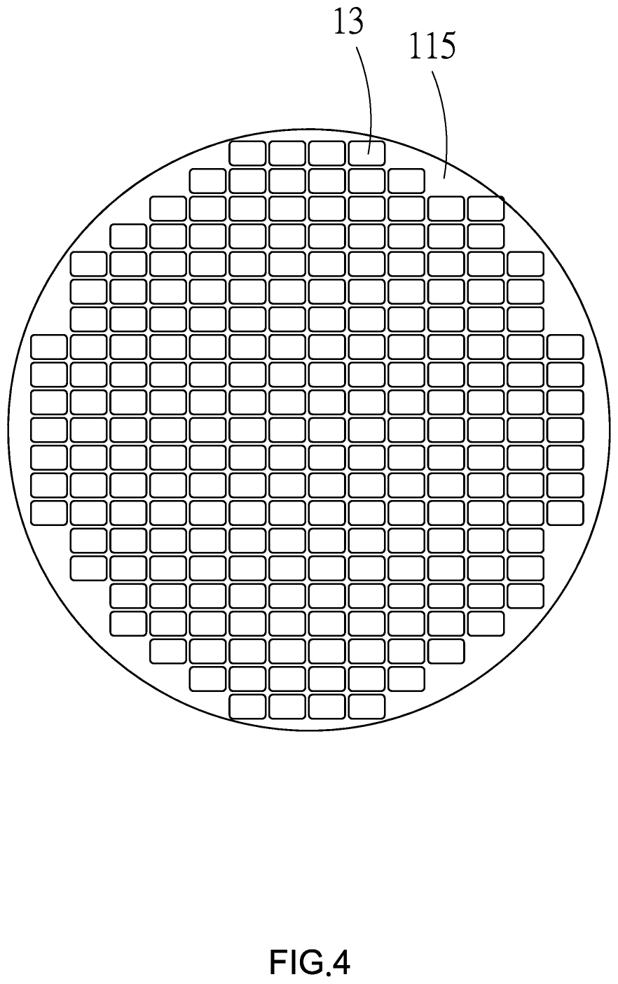

The manufacturing process of a capacitor unit according to the present invention is described as follows. First, referring to FIG. 1, a carrier 11 (such as glass carrier) is provided. Then, referring to FIG. 2, a release layer 115 is formed on the carrier 11 by, for example, pasting or coating. Then, referring to FIGS. 3 and 4, a metallic layer 12 is formed on the release layer 115 by, for example, sputtering or electroplating deposition, and yellow light processing (exposure and development) and etching can be performed on the metallic layer 12 to define a plurality of metallic blocks 13.

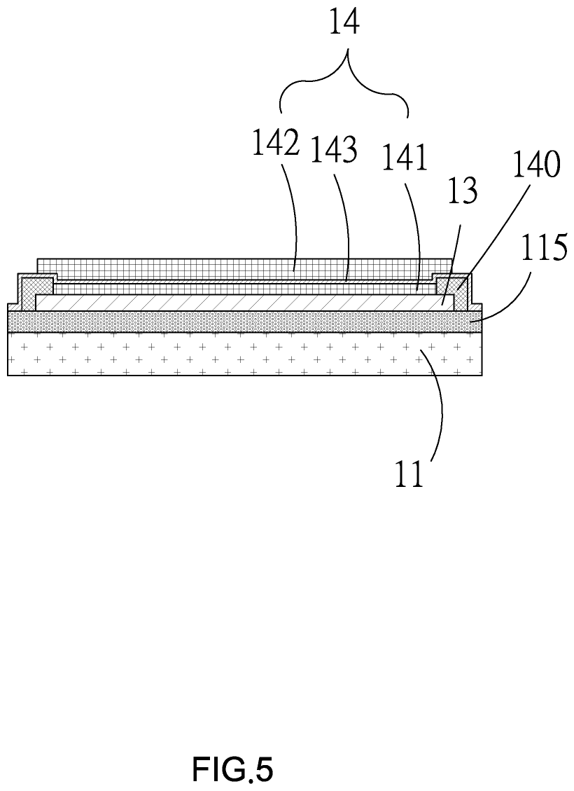

Then, referring to FIG. 5, a middle stacking structure 14 is formed on each of the metallic blocks 13. The middle stacking structure 14 includes a first capacitance conductive layer 141, a second capacitance conductive layer 142, and a capacitance insulation layer 143 located between the first capacitance conductive layer 141 and second capacitance conductive layer 142.

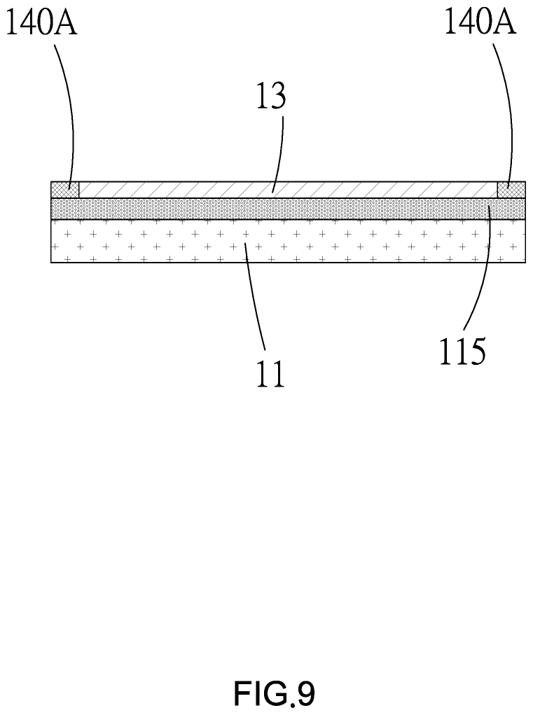

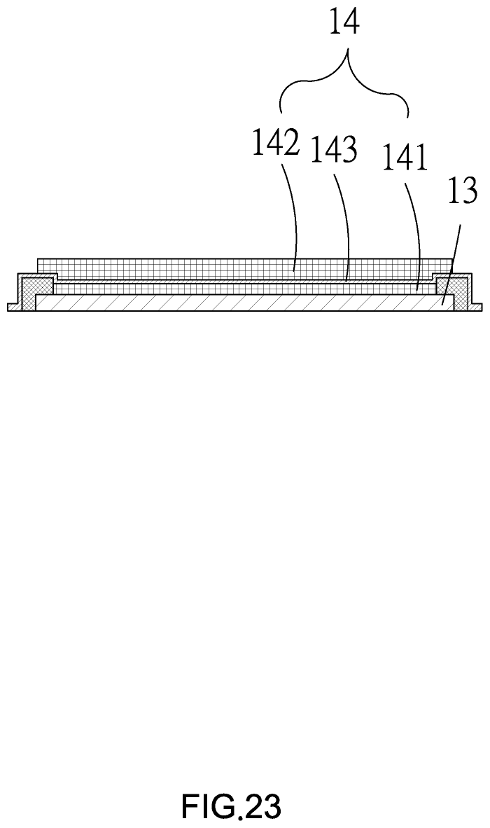

In more detail, as shown in FIG. 5, an insulating material layer 140 is applied and covers each of the metallic blocks 13 and exposed parts of the release layer 115. As shown in FIG. 9, the insulating material layer 140 is flattened to expose a top surface of each of the metallic blocks 13, and then the first capacitance conductive layer 141 is formed on and electrically connected to each of the exposed metallic blocks 13. The capacitance insulation layer 143 is subsequently formed to cover the first capacitance conductive layer 141 and the insulating material layer 140. The second capacitance conductive layer 142 is finally formed on the capacitance insulation layer 143, wherein the capacitance insulation layer 143 electrically isolates the first capacitance conductive layer 141 from the second capacitance conductive layer 142. Such a configuration allows a capacitor unit shown in FIG. 23 to be formed when the carrier 11 and the release layer 115 are removed, with the middle stacking structure 14 of the capacitor unit being in a planar stacked form.

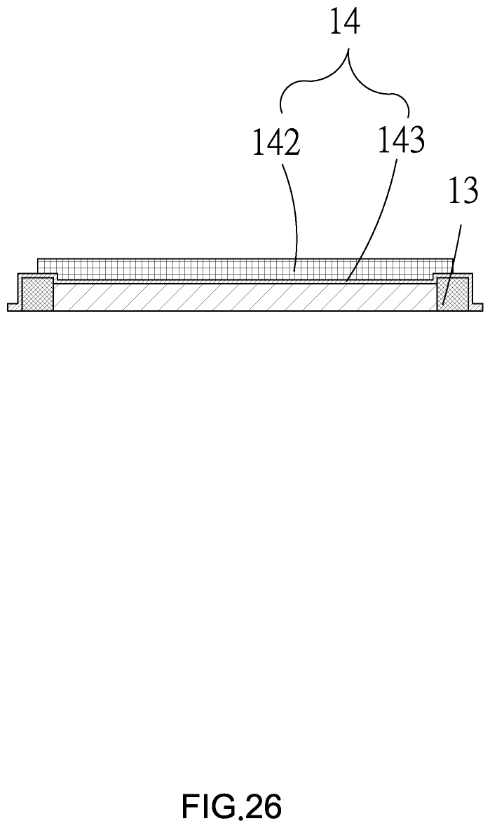

It should be noted that, the first capacitance conductive layer 141 and the corresponding one of the metallic blocks 13 can be integrally formed, or the first capacitance conductive layer 141 can be omitted, such that the capacitance insulation layer 143 covers the exposed metallic block 13 and the insulating material layer 140, and the second capacitance conductive layer 142 is provided on the capacitance insulation layer 143 that is to electrically isolate the metallic block 13 from the second capacitance conductive layer 142. This allows a capacitor unit shown in FIG. 26 to be formed when the carrier 11 and the release layer 115 are removed.

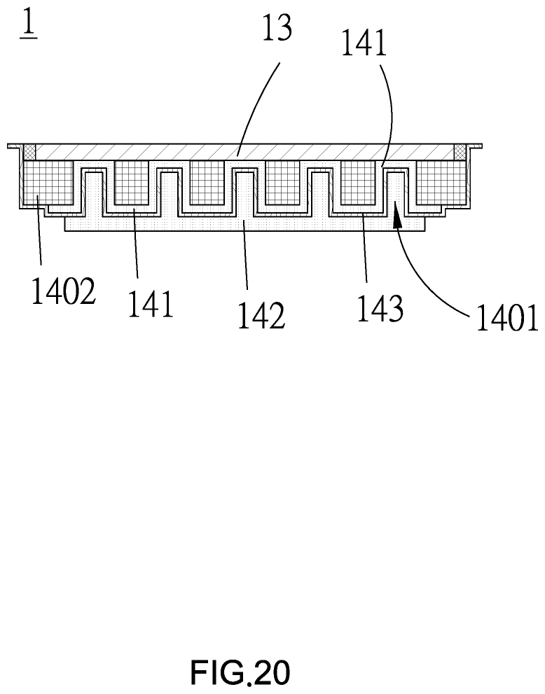

Moreover, in each of the middle stacking structures 14, a raised sub-structure 1402 can be formed by any suitable technique to make the middle stacking structure 14 increased in height. With such a raised middle stacking structure 14, a capacitor unit having a deep trench structure as shown in FIG. 20 can be obtained when the carrier 11 and the release layer 115 are removed.

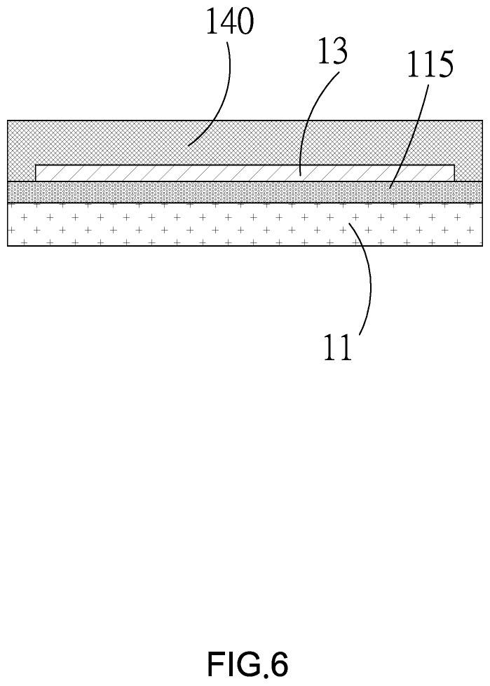

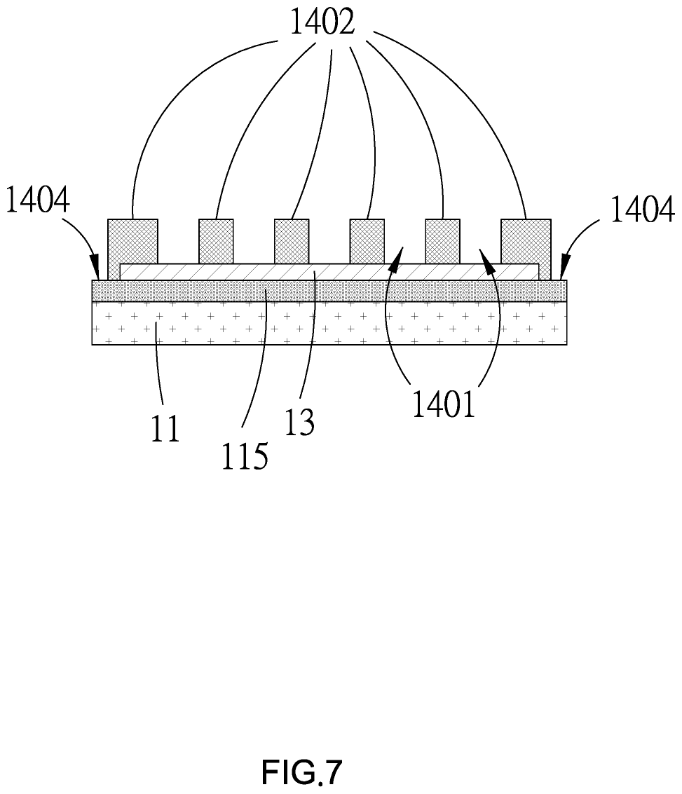

To form the raised sub-structure 1402, as shown in FIG. 6, the insulating material layer 140 with a predetermined thickness (serving as photoresist) can first be pressed or coated on each of the metallic blocks 13 and the exposed parts of the release layer 115, to be used as a structure layer of the capacitor unit 1. Then as shown in FIG. 7, the insulating material layer 140 is subjected to, for example, exposure, development and high-temperature curing procedures to form a plurality of trenches 1401 that expose the metallic blocks 13 and define the raised sub-structure 1402 on each of the metallic blocks 13, such that the raised sub-structure 1402 can be formed in the middle stacking structure 14 by photolithography.

Then, further as shown in FIG. 7, dividing gaps 1404 can be formed in the insulating material layer 140 to expose the release layer 115 between any adjacent two of the metallic blocks 13, so as to allow, for example, a subsequent cutting procedure to be performed on the dividing gaps 1404 to separate the adjacent metallic blocks 13.

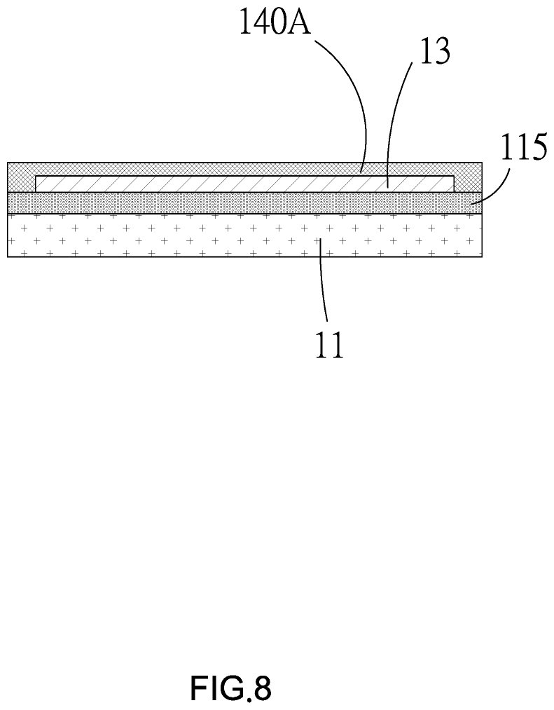

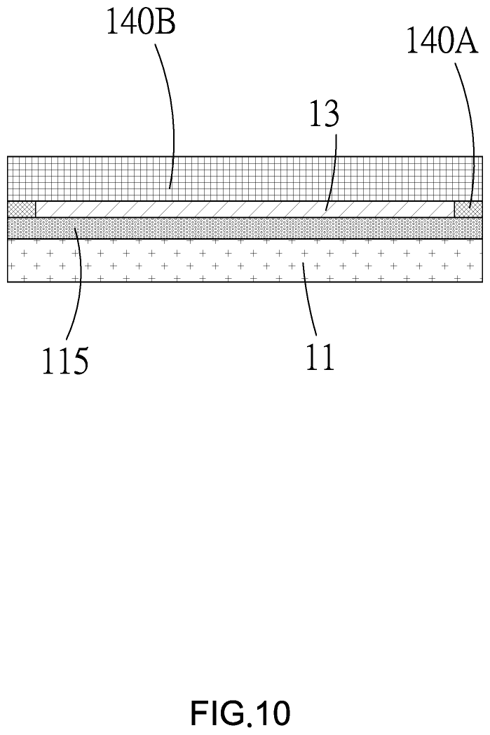

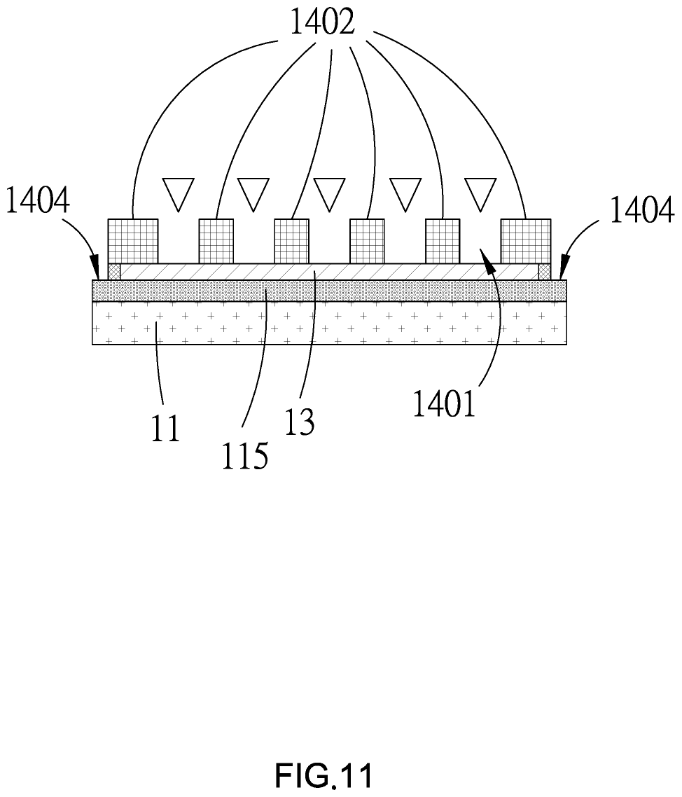

Further about forming the raised sub-structure 1402, alternatively, as shown in FIG. 8, a first insulating material layer 140A is first applied on each of the metallic blocks 13 and the exposed parts of the release layer 115 (that is, gaps between the metallic blocks 13). Then, as shown in FIG. 9, the first insulating material layer 140A is flattened to expose the top surface of each of the metallic blocks 13. Then, as shown in FIG. 10, a second insulating material layer 140B is formed on each of the metallic blocks 13 and the first insulating material layer 140A by bonding or adhesion, wherein the second insulating material layer 140B is made of a hard insulating material such as glass, quartz, ceramic material and so on. The second insulating material layer 140B can even be thinned by polishing. Then, as shown in FIG. 11, a plurality of trenches 1401 can be formed in the second insulating material layer 140B by laser drilling to expose the metallic blocks 13 and thus define the raised sub-structure 1402 on each of the metallic blocks 13, such that the raised sub-structure 1402 in the middle stacking structure 14 are thereby produced by such laser technique. Further, dividing gaps 1404 can be formed in the second insulating material layer 140B to expose the release layer 115 between any adjacent two of the metallic blocks 13, so as to allow, for example, a subsequent cutting procedure to be performed on the dividing gaps 1404 to separate the adjacent metallic blocks 13.

Further about forming the raised sub-structure 1402, alternatively, as shown in FIG. 8, a first insulating material layer 140A is first applied on each of the metallic blocks 13 and the exposed parts of the release layer 115 (that is, gaps between the metallic blocks 13). Then, as shown in FIG. 9, the first insulating material layer 140A is flattened to expose the top surface of each of the metallic blocks 13. Then, as shown in FIG. 10, a second insulating material layer 140B is formed on each of the metallic blocks 13 and the first insulating material layer 140A by bonding or adhesion, wherein the second insulating material layer 140B is made of a hard insulating material such as glass, quartz, ceramic material and so on.

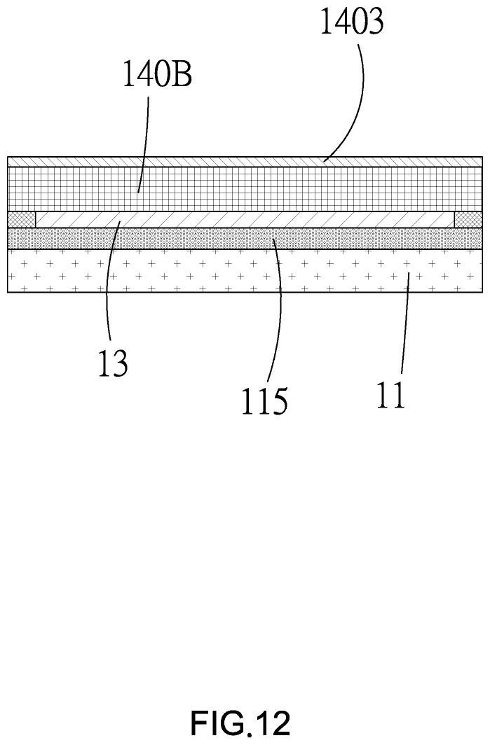

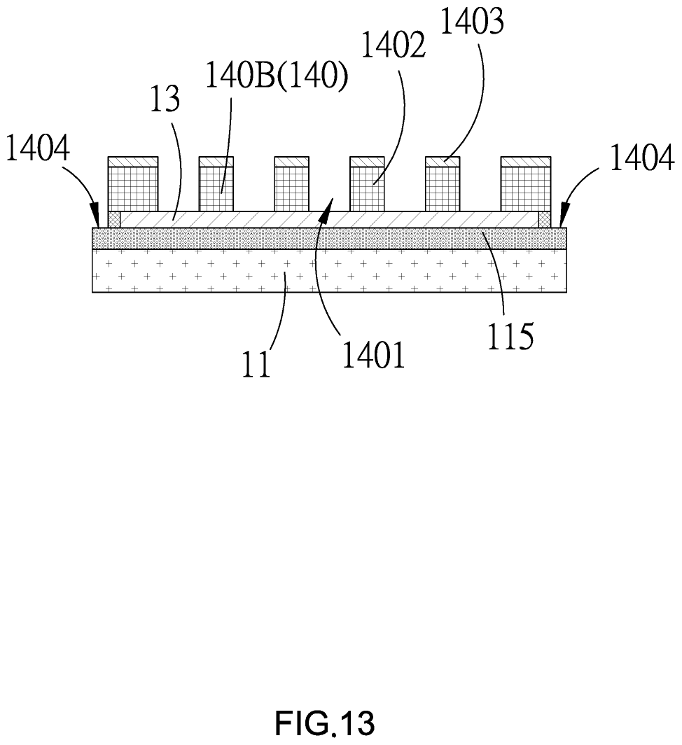

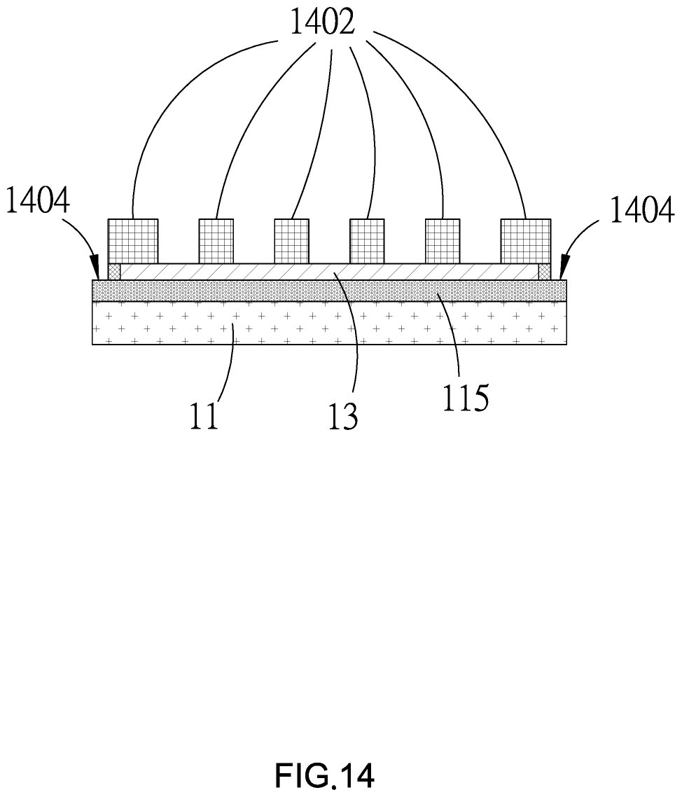

Then, as shown in FIG. 12, a photoresist layer 1403 is provided on the second insulating material layer 140B by dry etching. Then, as shown in FIG. 13, yellow light processing is adopted to define to-be-etched areas of the photoresist layer 1403, and areas of the second insulating material layer 140B, which correspond to the to-be-etched areas, are etched by using the dry etching technique to form a plurality of trenches 1401 in the second insulating material layer 140B to expose each of the metallic blocks 13. Then, as shown in FIG. 14, the photoresist layer 1403 on the second insulating material layer 140B is removed, and thus the raised sub-structure 1402 on each of the metallic blocks 13 is defined, such that the dry etching technique, such as deep reactive-ion etching (DRIE), can be adopted to produce the raised sub-structure 1402 in each of the middle stacking structures 14.

Further, dividing gaps 1404 can be formed in the second insulating material layer 140B to expose the release layer 115 between any adjacent two of the metallic blocks 13, so as to allow, for example, a subsequent cutting procedure to be performed on the dividing gaps 1404 to separate the adjacent metallic blocks 13.

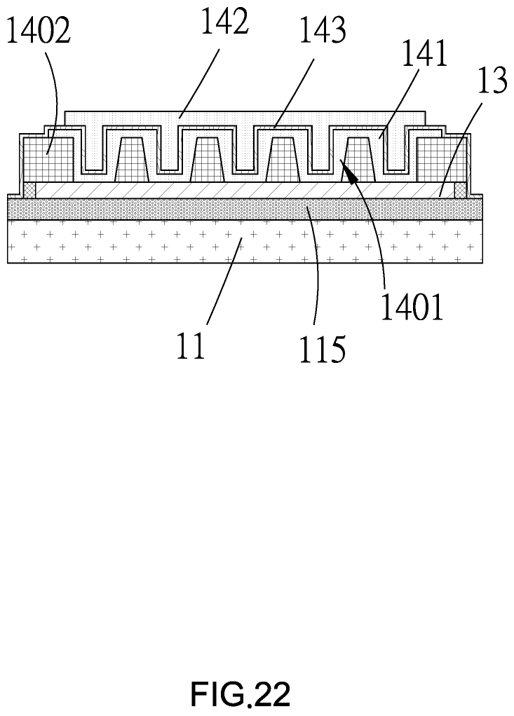

A horizontal cross section of each of the trenches 1401 can be polygonal, round or rectangular. As shown in FIG. 22, a vertical cross section of each of the trenches 1401 can be triangular, rectangular or trapezoid. Moreover, the raised sub-structure 1402 can have a height (but not limited to) of 5 to 150 micrometers, and the height is adjustable according to practical requirements.

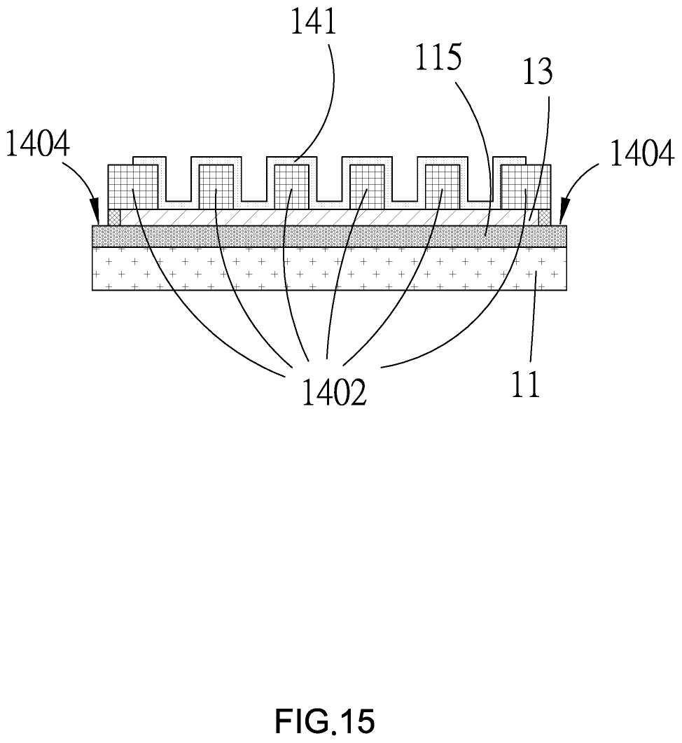

Subsequent to the above photolithography, laser or dry etching processing used in the formation of the raised sub-structure 1402, as shown in FIG. 15, the first capacitance conductive layer 141 having a substantially uniform thickness can be formed on the raised sub-structure 1402 and exposed parts of each of the metallic blocks 13.

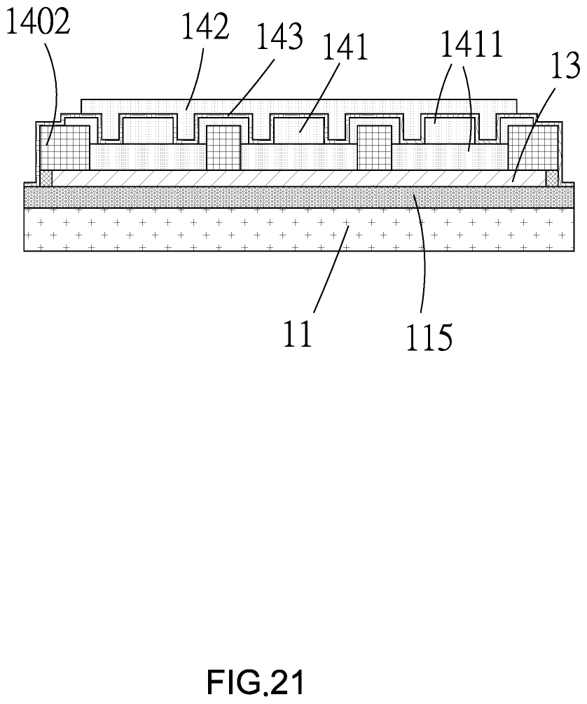

The first capacitance conductive layer 141 having a substantially uniform thickness can be formed by electroplating or electroplating-deposition, and is electrically connected to the exposed parts of the corresponding one of the metallic blocks 13, with the dividing gaps 1404 being exposed. The first capacitance conductive layer 141 includes at least one metallic sub-layer 1411. FIG. 21 shows the first capacitance conductive layer 141 having two metallic sub-layers 1411. The present invention is not limited to this configuration, and the number of the metallic sub-layers 1411 is adjustable according to practical requirements.

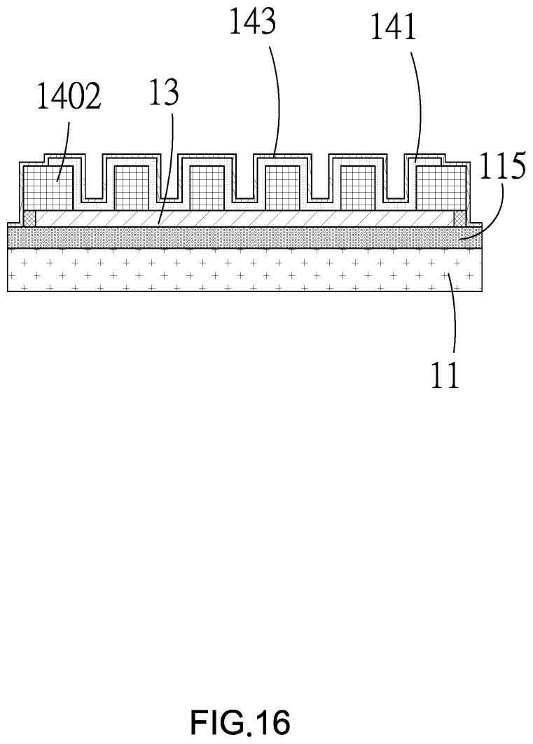

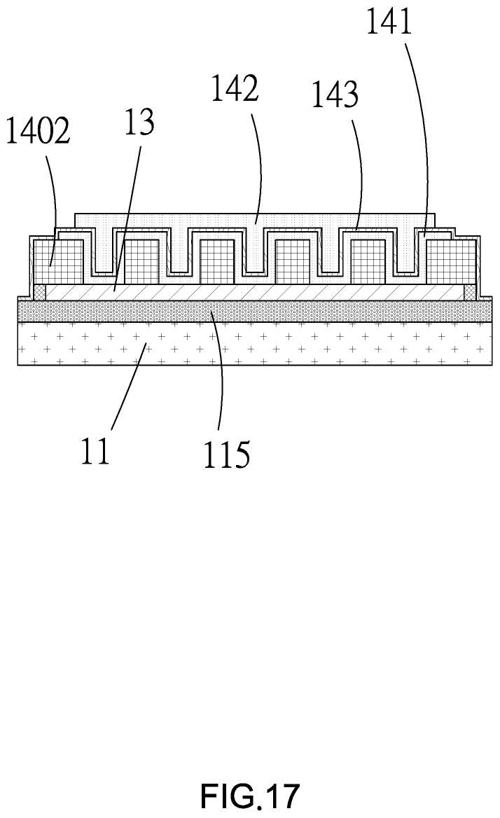

Then, as shown in FIG. 16, the capacitance insulation layer 143 having a substantially uniform thickness is formed along a surface of the first capacitance conductive layer 141. As shown in FIG. 17, the second capacitance conductive layer 142 is formed on the capacitance insulation layer 143, with a lower surface of the second capacitance conductive layer 142 extended along an upper surface of the capacitance insulation layer 143. The second capacitance conductive layer 142 can be formed by sputtering or electroplating-deposition to have a flat upper surface.

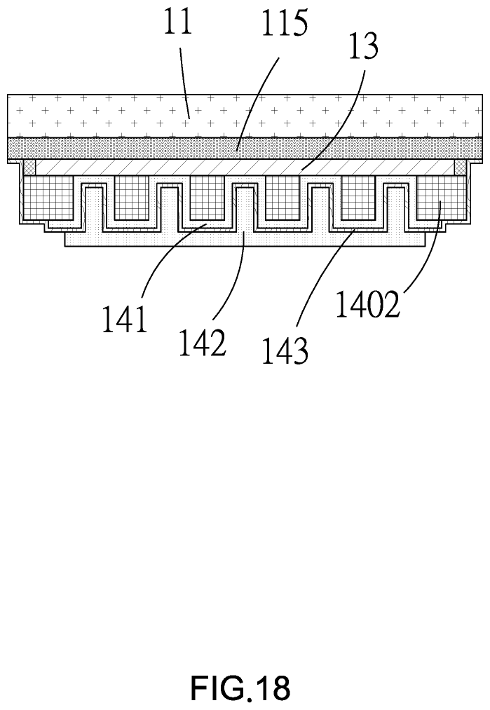

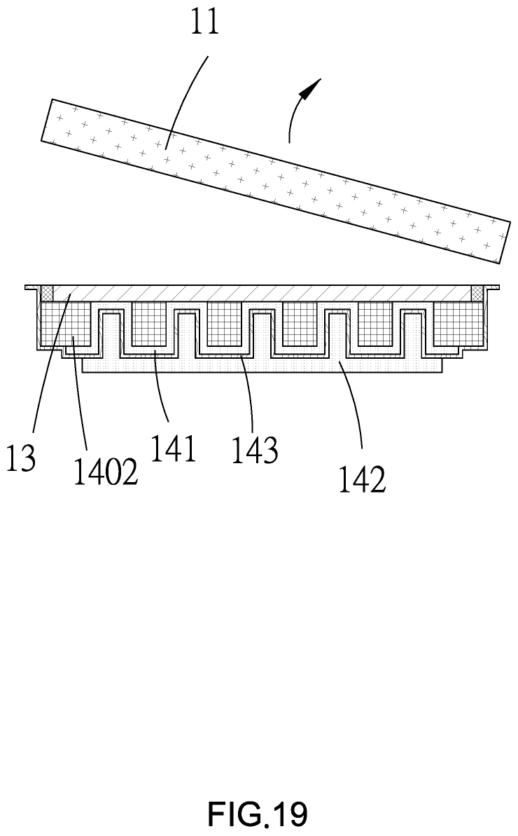

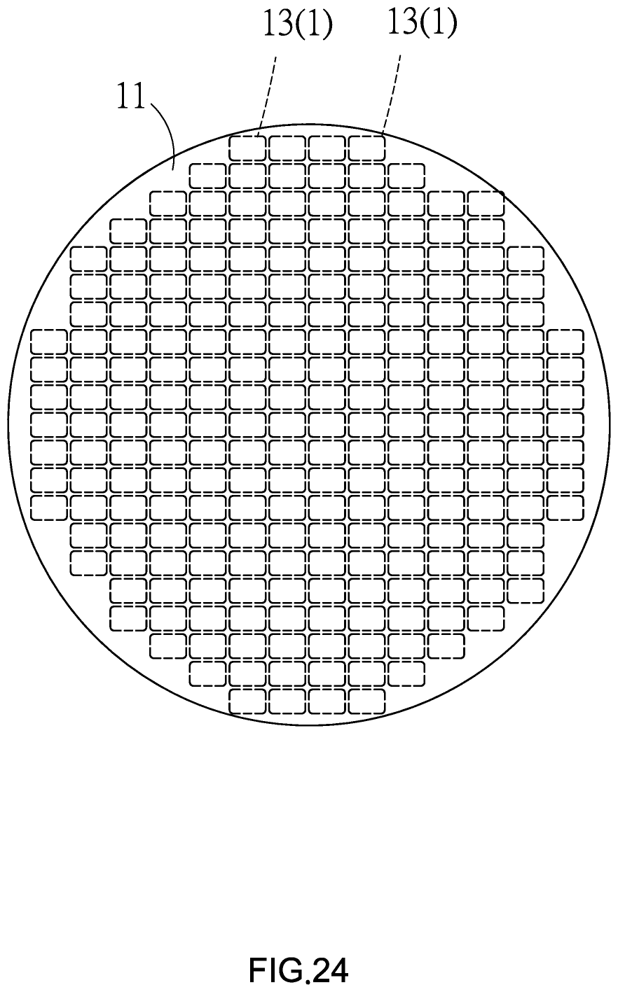

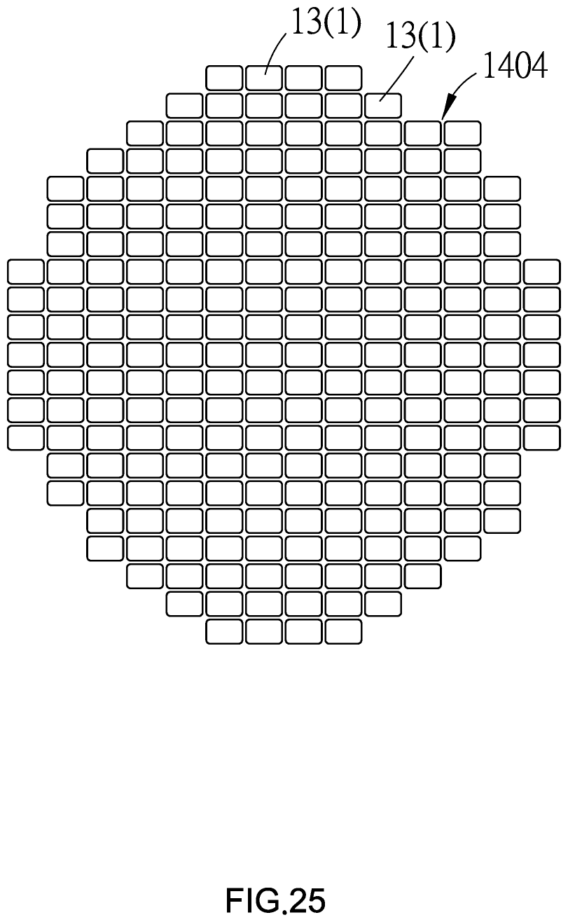

Referring to FIG. 18, the structure of FIG. 17 is turned upside down, with the carrier 11 located at the top of the structure as shown in FIG. 24. Then, as shown in FIGS. 19 to 20, light or laser processing is performed to crack the release layer 115 and remove the carrier 11 so as to expose the metallic blocks 13, and then the dividing gaps 1404 are subjected to a dividing technique to form a plurality of individual capacitor units 1 shown in FIG. 25. Each of the exposed metallic blocks 13 serves as a bottom electrode 13 of each of the capacitor units 1, and the second capacitance conductive layer 142 of the middle stacking structure 14 serves as a top electrode 142 of each of the capacitor units 1.

The capacitor unit 1 according to the present invention selectively includes the bottom electrode 13, the raised sub-structure 1402, the first capacitance conductive layer 141, the capacitance insulation layer 143 and the top electrode 142, as shown in FIG. 20. The raised sub-structure 1402 is formed over the bottom electrode 13, and has a plurality of trenches 1401 exposing parts of the bottom electrode 13. The first capacitance conductive layer 141 has a substantially uniform thickness, and is provided over the raised sub-structure 1402 and the exposed parts of the bottom electrode 13. The capacitance insulation layer 143 has a substantially uniform thickness, and is provided over parts of the first capacitance conductive layer 141. The top electrode 142 covers parts of the capacitance insulation layer 143, wherein a side of the top electrode 142 abutting the capacitance insulation layer 143 is extended along a surface of the capacitance insulation layer 143, and another side of the top electrode 142 facing away from the capacitance insulation layer 143 is exposed and flat.

The first capacitance conductive layer 141 includes at least one metallic sub-layer 1411. FIG. 21 shows the first capacitance conductive layer 141 having two metallic sub-layers 1411. The present invention is not limited to this configuration, and the number of the metallic sub-layers 1411 is adjustable according to practical requirements.

A horizontal cross section of each of the trenches 1401 can be polygonal, round or rectangular. As shown in FIG. 22, a vertical cross section of each of the trenches 1401 can be triangular, rectangular or trapezoid.

Therefore, the above manufacturing process of a capacitor unit according to the present invention can produce a double sided capacitor unit with a top electrode and a bottom electrode. By forming a raised sub-structure in the capacitor unit, and allowing multiple capacitance conductive layers to be formed in line with a contour of the raised sub-structure, the capacitance conductive layers can have an increased extension length and thus the double sided capacitor unit is made with high capacitance. Further, the present invention adopts the DRIE technique of semiconductor processing to form a deep trench structure, which can greatly increase its area so as to produce such a deep trench capacitor with high capacitance, thereby allowing the double sided capacitor unit to advantageously have a compact size while high capacitance. Moreover, the capacitor unit with the deep trench structure according to the invention is not made of a base material and has no limit on its depth, which thereby has higher capacitance than the conventional planar type capacitor unit.

Further in the present invention, there is a plurality of capacitance stacking structures formed on a carrier to compose a capacitance integrated structure comprising a plurality of capacitor units. Thus, a mass of capacitor units are fabricated simply after the carrier is removed, with no more cutting procedure being needed. Compared to the conventional MLCC manufacturing process, the present invention undoubtedly simplifies the manufacturing process and structure of capacitors, makes it easier to reduce capacitor area, and achieves better product precision, such that the present invention avoids a high temperature calcination procedure of the conventional MLCC manufacturing process and thus reduces manufacture costs.

The examples above are only illustrative to explain principles and effects of the invention, but not to limit the invention. It will be apparent to those skilled in the art that modifications and variations can be made without departing from the scope of the invention. Therefore, the protection range of the rights of the invention should be as defined by the appended claims.

What is claimed is:

1. A manufacturing process of a capacitor unit, including:
providing a carrier;
forming a metallic layer on the carrier, defining a plurality of metallic blocks of the metallic layer, and forming a middle stacking structure on each of the metallic blocks, wherein the middle stacking structure includes a first capacitance conductive layer, a second capacitance conductive layer, and a capacitance insulation layer located between the first capacitance conductive layer and the second capacitance conductive layer, wherein the first capacitance conductive layer is electrically connected to the corresponding one of the metallic blocks; and
removing the carrier to expose the metallic blocks so as to form a plurality of independent capacitor units;
wherein each of the metallic blocks is used as a bottom electrode of each of the capacitor units, and the second capacitance conductive layer of the middle stacking structure is used as a top electrode of each of the capacitor units.

2. The manufacturing process of a capacitor unit according to claim 1, wherein the carrier is a glass carrier.

3. The manufacturing process of a capacitor unit according to claim 1, further including: forming a release layer on the carrier, and forming the metallic layer on the release layer.

4. The manufacturing process of a capacitor unit according to claim 1, wherein the step of forming a middle stacking structure on each of the metallic blocks further includes:
forming the first capacitance conductive layer on each of the metallic blocks;
forming the capacitance insulation layer on the first capacitance conductive layer; and
forming the second capacitance conductive layer on the capacitance insulation layer.

5. The manufacturing process of a capacitor unit according to claim 1, wherein the step of forming a middle stacking structure on each of the metallic blocks further includes:
forming an insulating material layer on each of the metallic blocks;
forming a plurality of trenches in the insulating material layer to expose each of the metallic blocks to define a raised sub-structure on each of the metallic blocks;
forming the first capacitance conductive layer having a substantially uniform thickness along a surface of the raised sub-structure and an exposed surface of each of the metallic blocks;
forming the capacitance insulation layer having a substantially uniform thickness along a surface of the first capacitance conductive layer; and
forming the second capacitance conductive layer on the capacitance insulation layer, wherein the second capacitance conductive layer has a lower surface extended along a surface of the capacitance insulation layer.

6. The manufacturing process of a capacitor unit according to claim 5, wherein the horizontal cross section of each of the trenches can be polygonal, round or rectangular.

7. The manufacturing process of a capacitor unit according to claim 5, wherein the vertical cross section of each of the trenches can be triangular, rectangular or trapezoid.

8. The manufacturing process of a capacitor unit according to claim 5, wherein the raised sub-structure has a height of 5 to 150 micrometers.

9. The manufacturing process of a capacitor unit according to claim 5, wherein further including: the use of the photolithography, laser or dry etching processing used in the formation of the raised sub-structure.

10. The manufacturing process of a capacitor unit according to claim 5, wherein the first capacitance conductive layer and the second capacitance conductive layer are formed by sputtering or electroplating.

11. The manufacturing process of a capacitor unit according to claim 1, wherein the first capacitance conductive layer includes at least one metallic sub-layer.

12. A capacitor unit including:
a bottom electrode;
a raised sub-structure provided on the bottom electrode and having a plurality of trenches exposing the bottom electrode;
a first capacitance conductive layer formed on a surface of the raised sub-structure and a surface of the bottom electrode, the first capacitance conductive layer having a substantially uniform thickness;
a capacitance insulation layer formed on a surface of the first capacitance conductive layer and having a substantially uniform thickness; and
a top electrode covering a surface of the capacitance insulation layer, wherein a side of the top electrode abutting the capacitance insulation layer is extended along the surface of the capacitance insulation layer.

13. The capacitor unit according to claim 12, wherein the first capacitance conductive layer has at least one metallic sub-layer.

14. The capacitor unit according to claim 12, wherein the horizontal cross section of each of the trenches can be polygonal, round or rectangular.

15. The capacitor unit according to claim 12, wherein the vertical cross section of each of the trenches can be triangular, rectangular or trapezoid.

16. A manufacturing process of a capacitor unit, including:
providing a carrier;
forming a metallic layer on the carrier, and defining a plurality of metallic blocks of the metallic layer;
forming a middle stacking structure on each of the metallic blocks, wherein the middle stacking structure includes a second capacitance conductive layer, and a capacitance insulation layer located between each of the metallic blocks and the second capacitance conductive layer; and
removing the carrier to expose the metallic blocks so as to form a plurality of independent capacitor units;
wherein each of the metallic blocks is used as a bottom electrode of each of the capacitor units, and the second capacitance conductive layer of the middle stacking structure is used as a top electrode of each of the capacitor units.
